(19) United States
(12) Patent Application Publication
(10) Pub. No.: US 2013/0269745 A1
(43) Pub. Date: Oct. 17, 2013

(54) THERMOELECTRIC CONVERSION MODULE

(71) Applicant: Panasonic Corporation, Osaka (JP)

(72) Inventors: Takaaki Higashida, Osaka (JP); Takashi Kubo, Osaka (JP); Yoshihisa Ohido, Osaka (JP); Kaori Toyoda, Hyogo (JP); Satoshi Maeshima, Hyogo (JP)

(21) Appl. No.: 13/836,920

(22) Filed: Mar. 15, 2013

(30) Foreign Application Priority Data
Apr. 3, 2012 (JP) 2012-084548
Feb. 6, 2013 (JP) 2013-021388

(51) Int. Cl. H01L 35/30; H01L 35/32

(52) U.S. Cl. CPC H01L 35/30; H01L 35/32
USPC 136/224

(57) ABSTRACT

A thermoelectric conversion module in which a high-density disposition is easily performed and connection reliability is high is supplied. A thermoelectric conversion module is provided, which includes a plurality of p-type thermoelectric conversion elements and a plurality of n-type thermoelectric conversion elements that are alternately arranged. and electrically connected in series, and a plurality of heat-radiation fins that are disposed in one end side of the plurality of p-type thermoelectric conversion elements and the plurality of n-type thermoelectric conversion elements in side surfaces of the plurality of p-type thermoelectric conversion elements and the plurality of n-type thermoelectric conversion elements. The plurality of heat-radiation fins intersect the long axis directions of the p-type thermoelectric conversion elements and the n-type thermoelectric conversion element and connect the p-type thermoelectric conversion elements and the n-type thermoelectric conversion element to each other.

### CROSS REFERENCE TO RELATED APPLICATIONS

This application is entitled to the benefit of Japanese Patent Application No. 2012-084548, filed Apr. 3, 2012, and Japanese Patent Application No. 2013-021388, filed Feb. 6, 2013, the entire contents of which are incorporated by reference herein.

### TECHNICAL FIELD

The present invention relates to a thermoelectric conversion module.

### BACKGROUND ART

A thermoelectric conversion element is an element which performs conversion between heat and electric power using Peltier effect or Seeback effect. In the thermoelectric conversion element, since the structure is simple, the handling is easy, and stable characteristics can be maintained, recently, the extensive use attracts attention. When the thermoelectric conversion element is used as an electronic cooling element, local cooling or an accurate temperature control in the vicinity of room temperature can be performed. Thereby, research has been widely processed for making temperature of an optoelectronics, a semiconductor laser or the like constant.

The thermoelectric conversion module, which is used in the electronic cooling element or thermoelectric power generation described above, has a structure shown in FIG. 3. In the thermoelectric conversion module shown in FIG. 3, a pn element pair is arranged in series in plural so as to configure the thermoelectric conversion module, the pn element pair comprising p-type thermoelectric conversion element (p-type semiconductor) 5 and n-type thermoelectric conversion element (n-type semiconductor) 6 connected to each other through connection electrode (metal electrode) 7. Moreover, in FIG. 3, reference numerals 8 and 9 indicate outer connection terminals, a reference numeral 10 indicates a ceramic substrate, and a reference numeral H is an arrow indicating a direction in which heat flows (for example, refer to PTL 1). Since one ends of p-type thermoelectric conversion element 5 and n-type thermoelectric conversion element 6 are heated and the other ends are cooled, a current flows in the pn element pairs.

It is preferable that a thermoelectric conversion material of the thermoelectric conversion element be a material in which a performance index Z (=α²/πK) represented by Seebeck coefficient α, a specific resistance ρ, and a heat conductivity K which are constants of unique characteristics of a material is large in an utilizable temperature range of the element. As an example of a crystal material which is generally used as the thermoelectric conversion material, there is a Bi₂Te₃ based material. However, the crystal material has a remarkable cleavage property. Thereby, when an ingot is subjected to slicing or dicing in order to obtain the thermoelectric conversion element, cracks or defects occur. Therefore, it is known that there is a problem in that a manufacturing yield of the thermoelectric conversion element is considerably decreased.

In order to solve the above-described problems, a method is tried which manufactures the thermoelectric conversion element 1) by heating and melting material powder mixed so as to have a desired composition, 2) by forming a solid solution ingot of a thermoelectric conversion material having a rhombohedron structure (hexagonal crystal structure) from the heated melt, 3) by crushing the solid solution ingot so as to obtain solid solution powders, 4) equalizing particle diameters of the solid solution powder, 5) by pressurizing and sintering the solid solution powder in which the diameters are equalized, and 6) by hot-plastically deforming and extending the powder sintered body (for example, refer to PTL 2). In the obtained thermoelectric conversion element, the crystal grains of the powder sintered texture are oriented in a crystal orientation in which a performance index is excellent.

Moreover, as a manufacturing method of the thermoelectric conversion element module in the related art, a method is known which includes 1) manufacturing a metal ingot, 2) preparing base powder having a mean powder particle diameter of 0.1 μm or more and less than 1 μm by crushing the metal ingot in a vacuum in which oxygen concentration is 100 ppm or less or in an atmosphere of inert gas, and 3) sintering the base powder by resistance-heating the base powder while applying a pressure to the base powder (for example, refer to PTL 3). In the sintering, a pulse-shaped current flows to the base powder, the base powder is sintered by the Joule heat, and also a pressure of 100 kg/cm² or more and 1,000 kg/cm² or less (9.8 MPa or more and 98.1 MPa or less) is applied to the base powder during the sintering. According to the manufacturing method, a thermoelectric conversion material in which the crystal grain diameter is minute and workability is excellent is manufactured.

In addition, a heat-radiation member may be provided in a thermoelectric conversion module (for example, refer to PTLs 4 to 11). For example, in PTLs 6, 7, 10, and 11, a configuration is suggested in which heat-radiation fins are provided on an end surface (an end surface of a side which is cooled at the time of generation of electricity) of the thermoelectric conversion element.

### CITATION LIST

### Patent Literature

### PTL 1: Japanese Patent Application Laid-Open No. 2011-009405

PTL 2: Japanese Patent Application Laid-Open No. HEI 11-261119

### PTL 3: Japanese Patent Application Laid-Open No. 2003-298122

### PTL 4: Japanese Patent Application Laid-Open No. 2005-294695

### PTL 5: United States Patent Application Laid-Open No. 2005/0217714

PTL 6: PCT International Publication No. WO 2004/001865

### PTL 7: United States Patent Application Laid-Open No. 2005/172981

PTL 8: Japanese Patent Application Laid-Open No. HEI 11-40864

### PTL 9: Japanese Patent Application Laid-Open No. 2006-93440

PTL 10: Japanese Patent Application Laid-Open No. HEI 09-97930

### PTL 11: United States Patent No. 5724818

### SUMMARY OF INVENTION

### Technical Problem

In the thermoelectric conversion element module, a heating portion (high temperature portion) and a cooling portion (low temperature portion) are required in the thermoelectric conversion element in order to generate electricity, and thus, it is necessary to provide a temperature difference between both. However, when the temperature difference occurs between the heating portion and the cooling portion of the thermoelectric conversion element, thermal stress occurs between the thermoelectric conversion element and the interconnect as connection electrode due to a difference of thermal expansion. Thereby, when the temperature difference between the heating portion and the cooling portion is increased so as to obtain a large potential difference, the stress is increased at a portion joined between the thermoelectric conversion element and the connection electrode, and thus, the joining reliability is decreased.

The inventor examined that heat accumulated in the cooling portion was effectively radiated to the outside environment (the outside air) by disposing a heat-radiation fin in the cooling portion of the thermoelectric conversion module or the vicinity of the cooling portion. That is, the inventor examined that thermal radiation efficiency from the cooling portion was increased by providing the heat-radiation fin in the portion near the cooling portion.

Moreover, the inventor controlled a temperature profile from the heating portion to the cooling portion of the thermoelectric conversion module by providing a plurality of heat-radiation fins. In addition, the inventor reviewed that structural strength of the thermoelectric conversion module was increased by providing the heat-radiation fin as a reinforcing member. Particularly, the inventor reviewed that stress in an interconnecting portion (the stress which occurs between an interconnect and the thermoelectric conversion element) was suppressed by increasing the structural strength.

### Solution to Problem

According to an aspect of the present invention, there is provided a thermoelectric conversion module that includes a plurality of p-type thermoelectric conversion elements and a plurality of n-type thermoelectric conversion elements that are alternately arranged and electrically connected in series. The thermoelectric conversion module includes a plurality of heat-radiation fins that are offset to one end side of the plurality of p-type thermoelectric conversion elements and the plurality of n-type thermoelectric conversion elements with respect to long axis directions thereof. The plurality of heat-radiation fins are disposed on lateral surfaces of the plurality of p-type thermoelectric conversion elements and the plurality of n-type thermoelectric conversion elements with respect to the long axis directions thereof. The plurality of heat-radiation fins intersects the long axis directions of the p-type thermoelectric conversion elements and the n-type thermoelectric conversion element. And also the plurality of heat-radiation fins connects the p-type thermoelectric conversion elements and the n-type thermoelectric conversion element to each other.

### Advantageous Effects of Invention

According to the thermoelectric conversion module of the present invention, since stress between the thermoelectric conversion elements and a connection electrode is alleviated during generation of electricity, the thermoelectric conversion module having high connection reliability can be provided. Moreover, since the heat-radiation fin is provided as a member for positioning the thermoelectric conversion elements which configure the thermoelectric conversion module, structural strength of the thermoelectric conversion module is increased, and further arrangement density of the thermoelectric conversion elements can be increased.

### BRIEF DESCRIPTION OF DRAWINGS

FIG. 1 is a schematic view of a thermoelectric conversion module according to Embodiment 1;

FIGS. 2A to 2G is a schematic view showing a manufacturing process of the thermoelectric conversion module according to Embodiment 1; and

FIG. 3 is a schematic view showing a thermoelectric conversion module in the related art.

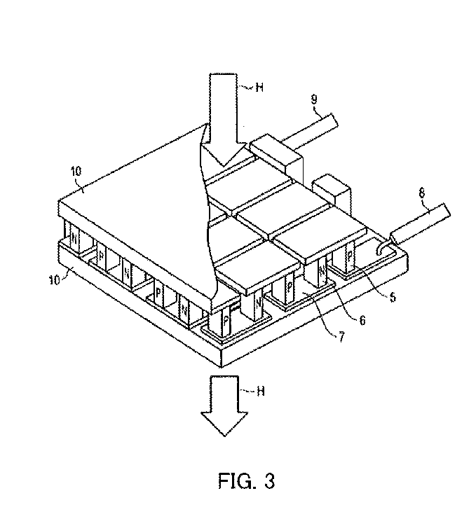

### DESCRIPTION OF EMBODIMENTS

Hereinafter, an embodiment of the present invention will be described with reference to the drawings.

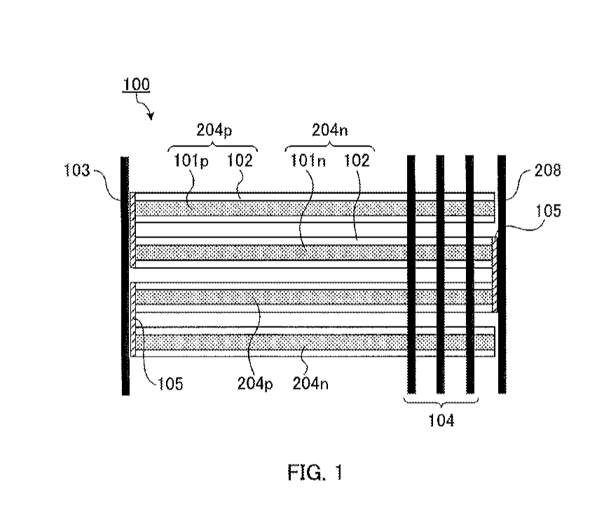

FIG. 1 is a schematic view of a thermoelectric conversion module according to Embodiment 1. In FIG. 1, thermoelectric conversion module 100 includes p-type thermoelectric conversion elements 204p and n-type thermoelectric conversion elements 204n, thermo-uniformity plate 103, heat-radiation fins 104, interconnects 105, and interconnection plate 208.

P-type thermoelectric conversion element 204p includes p-type thermoelectric conversion material 101p and tubular heat-resistant insulating material 102. N-type thermoelectric conversion element 204n includes n-type thermoelectric conversion material 101n and tubular heat-resistant insulating material 102. Interconnect 105 electrically connects p-type thermoelectric conversion material 101p of p-type thermoelectric conversion element 204p with n-type thermoelectric conversion material 101n of n-type thermoelectric conversion element 204n.

In this way, thermoelectric conversion element 204 (204p and 204n) includes thermoelectric conversion material 101 (101p and 101n) and tubular heat-resistant insulating material 102, and interconnect 105 is joined to not only an end surface of thermoelectric conversion material 101 but also an end surface of tubular heat-resistant insulating material 102. Thereby, compared a case where interconnect 105 is joined to only thermoelectric conversion material 101, joining force between interconnect 105 and thermoelectric conversion element 204 is increased. As a result, reliability of the portion joined between thermoelectric conversion element 204 and interconnect 105 is increased.

Moreover, since thermoelectric conversion element 204 includes thermoelectric conversion material 101 and tubular heat-resistant insulating material 102, even when conversion material 101 and insulating material 102 are disposed closely contacting with each other in thermoelectric conversion module 100, thermoelectric conversion elements 204 are electrically insulated with each other. Thereby, thermoelectric conversion elements 204 are easily arranged in high density in thermoelectric conversion module 100.

On the other hand, thermoelectric elements which include thermoelectric conversion materials which are not covered with the heat-resistant insulating materials are electrically connected, when such elements are arranged with contacting each other. Therefore, such thermoelectric conversion elements have to be certainly separated from each other. Thereby, the thermoelectric conversion elements which are composed of the thermoelectric conversion materials are difficult to be arranged in high density, and the extracted output is decreased.

However, in the thermoelectric conversion module of the present invention, it is preferable that thermoelectric conversion elements 204 be separated from each other. The reason is because the heat generated in thermoelectric conversion elements 204 can be effectively radiated. Thermoelectric conversion elements 204 which are arranged to be separated from each other are connected to or fixed each other by heat-radiation fins 104.

Thermo-uniformity plate 103 may be a plate member which is formed of an insulating material having high thermal conductivity. The insulating material having high thermal conductivity may be ceramic, rubber including a heat-radiation filler, or the like. It is preferable that interconnect 105 be disposed on thermo-uniformity plate 103. Thermo-uniformity plate 103 and interconnect 105 may be joined by adhesive having heat resistance. Alternately, interconnect 105 may be line-patterning by etching a metal film formed on thermo-uniformity plate 103, or the like.

Thermo-uniformity plate 103 is a part which contacts the high temperature member and is heated during a generation of electricity with thermoelectric conversion module 100. Thermo-uniformity plate 103 diffuses the temperature of the contact portion with the high temperature portion so as to equalize a temperature in the thermo-uniformity plate 103 of thermoelectric conversion module 100. By equalizing the temperature in the thermo-uniformity plate 103, electromotive forces and heat transport capacities of thermoelectric conversion elements 204 which are included in thermoelectric conversion module 100 can be equalized.

It is preferable that heat-radiation fin 104 be a plate having high thermal conductivity, and for example, heat-radiation fin 104 may be a metal plate. For example, a metal having high heat radiation may include aluminum, copper, or the like. Heat-radiation fin 104 is offset to one end side (right side in the drawing) of both end sides of the thermoelectric conversion elements (204p and 204n). And heat-radiation fin 104 is disposed on lateral surfaces of the thermoelectric conversion elements (204p and 204n).

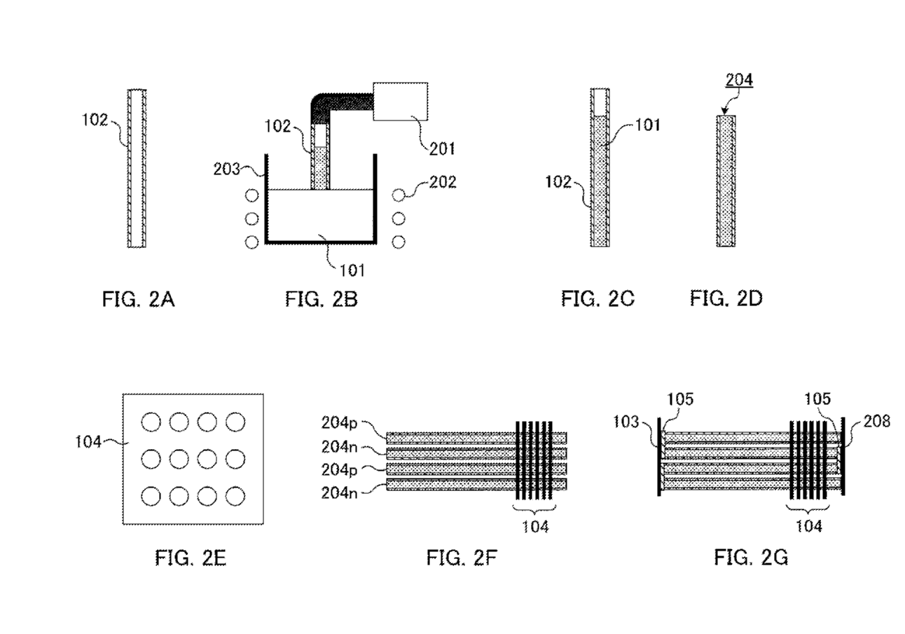

It is preferable that a heat-radiation plate configuring heat-radiation fin 104 have a plurality of through-holes (refer to FIG. 2E) therein, and p-type thermoelectric conversion element 204p or n-type thermoelectric conversion element 204n be inserted into each through-hole. That is, heat-radiation fin 104 intersects a long axis direction of thermoelectric conversion element 204.

Furthermore, it is preferable that thermoelectric conversion module 100 have plurality of heat-radiation fins 104. The reason is because efficiency of heat radiation can be increased. Moreover, it is preferable that plurality of heat-radiation fins 104 be arranged along a heat flow (from right side to left side in FIG. 1) of thermoelectric conversion module 100. The reason is because a temperature profile of thermoelectric conversion element (204p and 204n) is optimized. Moreover, since plurality of heat-radiation fins 104 are provided, structural strength of the module 100 is increased, and particularly, interconnect deviation which occurs due to stress between interconnect 105 and thermoelectric conversion element 204 can be suppressed.

In order to generate electricity in thermoelectric conversion module 100, it is preferable that thermo-uniformity plate 103 be heated. Due to the fact that thermo-uniformity plate 103 is heated, the other end (left side in the drawing) of both ends of the thermoelectric conversion elements (204p and 204n) is heated, and a temperature difference between the other end and one end (right side in the drawing) occurs. Moreover, since heat-radiation fin 104 cools the one end, a greater temperature difference occurs, and quantity of heat which flows in the thermoelectric conversion element is increased. As a result, the electromotive force of thermoelectric conversion module 100 is increased.

In the thermoelectric conversion module described as above, the temperature difference between the high temperature portion and the low temperature portion is easily increased, not only high electromotive force is provided, but also stress between the thermoelectric conversion element and the interconnect due to the temperature difference can be alleviated and mechanical strength (structural strength) of the thermoelectric conversion module is increased.

An example of a method of manufacturing thermoelectric conversion module 100 of FIG. 1 will be described with reference to FIGS. 2A to 2G. First, as shown in FIG. 2A, heat-resistant insulating material 102 configured in a hollow cylindrical shape is prepared. It is preferable that heat-resistant insulating material 102 be glass, particularly, heat-resistant glass (a material which is a kind of borosilicate glass in which SiO₂ and B₂O₃ are mixed and has coefficient of thermal expansion of approximately 3×10⁻⁶/K). An example of the heat-resistant glass which is generally known includes Pyrex (registered trademark) glass which is manufactured by Corning Corporation. In the present embodiment, heating-resistant insulating material 102, in which entire length L is 150 mm, and inner diameter d1 and outer diameter d2 are 1.8 mm and 3 mm respectively, is used.

Subsequently, one end of heat-resistant insulating material 102 of FIG. 2A is connected to vacuum pump 201, and the other end of heat-resistant insulating material 102 is disposed in carbon crucible 203 which is heated by induction coil 202. Carbon crucible 203 is filled with melted thermoelectric conversion material 101. In this present embodiment, thermoelectric conversion material 101 is Bi₂Te₃. Carbon crucible 203 is heated by induction coil 202, and the temperature of carbon crucible 203 is maintained to a temperature range of approximately 600 to 700° C. which is higher than the melting point of thermoelectric conversion material 101.

Thermoelectric conversion material 101 which is melted in carbon crucible 203 is sucked through the other end of heat-resistant insulating material 102, and is filled in a hollow space of heat-resistant insulating material 102. The suction of thermoelectric conversion material 101 is performed by decompressing the hollow space of heat-resistant insulating material 102 with vacuum pump 201. The degree of the decompression is different according to the shape or the like of heat-resistant insulating material 102. However, it is preferable that the degree be adjusted between approximately −50 to −100 kPa.

As described above, thermoelectric conversion material 101 is filled in the hollow space of heat-resistant insulating material 102, and thus, as shown in FIG. 2C, thermoelectric conversion element 204 is provided.

According to conditions in which thermoelectric conversion material 101 is sucked up, a part in the hollow space of thermoelectric conversion element 204 can be occur, the place being not sufficiently filled with thermoelectric conversion material 101. And also, a part of the thermoelectric conversion material 101 in the hollow space can be insufficiently crystallized. Thereby, the places are removed as necessary, and thus, thermoelectric conversion element 204 having a shape shown in FIG. 2D is obtained.

P-type thermoelectric conversion materials 101p and n-type thermoelectric conversion materials 101n are prepared and disposed in carbon crucible 203 respectively, and thus, p-type thermoelectric conversion elements 204p and n-type thermoelectric conversion elements 204n can be obtained respectively.

Subsequently, as shown in FIG. 2E, a plurality of metal plates (which become heat-radiation fin 104) having a plurality of through-holes therein are prepared. Thereafter, predetermined numbers of p-type thermoelectric conversion elements 204p and n-type thermoelectric conversion elements 204n are alternately arranged in the heat-radiation plates 104. At this time, p-type thermoelectric conversion elements 204p and n-type thermoelectric conversion elements 204n are inserted into through-holes of the heat-radiation plates. Thereby, as shown in FIG. 2F, thermoelectric conversion elements 204 are positioned and fixed.

Subsequently, as shown in FIG. 2G, interconnects 105 formed on thermo-uniformity plate 103 are electrically connected to thermoelectric conversion elements 204. Moreover, similarly, interconnect 105 which is disposed on interconnection plate 208 and thermoelectric conversion elements 204 are connected to each other, and thus, thermoelectric conversion module 100 can be obtained.

### INDUSTRIAL APPLICABILITY

As described above, according to the present invention, thermoelectric conversion elements can be arranged in high density, and the thermoelectric conversion module having high connection reliability can be obtained. Therefore, the thermoelectric conversion module of the present invention can be widely applied to cases where it is necessary to directly convert heat to electricity in various technical fields.

### REFERENCE SIGNS LIST

100 thermoelectric conversion module
101 thermoelectric conversion material
101p p-type thermoelectric conversion material
101n n-type thermoelectric conversion material
102 heat-resistant insulating material
103 thermo-uniformity plate
104 heat-radiation fin
105 interconnect
201 vacuum pump
202 induction coil
203 carbon crucible
204 thermoelectric conversion element
204p p-type thermoelectric conversion element
204n n-type thermoelectric conversion element
208 interconnection plate

1. A thermoelectric conversion module that includes a plurality of p-type thermoelectric conversion elements and a plurality of n-type thermoelectric conversion elements that are alternately arranged and electrically connected in series, comprising,
a plurality of heat-radiation fins that are offset to one end side of the plurality of p-type thermoelectric conversion elements and the plurality of n-type thermoelectric conversion elements with respect to long axis directions thereof, the plurality of heat-radiation fins being disposed on lateral surfaces of the plurality of p-type thermoelectric conversion elements and the plurality of n-type thermoelectric conversion elements with respect to the long axis directions thereof, wherein:
the plurality of heat-radiation fins intersect the long axis directions of the p-type thermoelectric conversion elements and the n-type thermoelectric conversion element, the plurality of heat-radiation fins connecting the p-type thermoelectric conversion elements and the n-type thermoelectric conversion element to each other.

2. The thermoelectric conversion module according to claim 1, wherein:
the one end is an end that is cooled during generation of electricity of the thermoelectric conversion module.

3. The thermoelectric conversion module according to claim 1, wherein:
the heat-radiation fin is a metal plate.

4. The thermoelectric conversion module according to claim 1, wherein:
the heat radiation fin is formed. of aluminum or copper.

5. The thermoelectric conversion module according to claim 1, wherein:
the p-type thermoelectric conversion, element includes a tubular heat-resistant insulting material and p-type thermoelectric conversion material that is filled in an inner portion of the tubular heat-resistant insulating material, and
the n-type thermoelectric conversion element includes a tubular heat-resistant insulting material and a n-type thermoelectric conversion material that is filled in an inner portion. of the tubular heat-resistant insulating material.

6. The thermoelectric conversion module according to claim 1, wherein
the heat-radiation fin is a metal plate that includes a. plurality of through-holes therein, and
the p-type thermoelectric conversion element or the n-type thermoelectric conversion element is inserted into each of the plurality of through-holes.
